(19) United States
(12) Patent Application Publication
(10) Pub. No.: US 2026/0155198 A1
(43) Pub. Date: Jun. 4, 2026

(54) STORAGE DEVICE FOR DETERMINING READ VOLTAGE AND OPERATING METHOD OF THE STORAGE DEVICE

(71) Applicant: SK hynix Inc, Icheon-si (KR)

(72) Inventors: Sang Ho YUN, Icheon-si (KR); Jang Seob KIM, Icheon-si (KR); Hong Sik YUN, Icheon-si (KR); Jeong Myung LEE, Icheon-si (KR); Hyuk Min KWON, Icheon-si (KR)

(21) Appl. No.: 19/361,966

(22) Filed: Oct. 17, 2025

(30) Foreign Application Priority Data
Nov. 29, 2024 (KR) 10-2024-0174960

(51) Int. Cl. G11C 29/50; G11C 16/04; G11C 16/26

(52) U.S. Cl. CPC G11C 29/50004; G11C 16/26; G11C 16/0483

(57) ABSTRACT

A semiconductor device, and more particularly, a storage device includes a memory device including a plurality of memory cells corresponding to a plurality of threshold voltage distributions and capable of improving the success rate of a read operation; and a memory controller determining an optimal read voltage, which is used for a read operation of target memory cells corresponding to a first threshold voltage distribution among the plurality of threshold voltage distributions, based on an average threshold voltage of the first threshold voltage distribution, a standard deviation of the first threshold voltage distribution, and a number of error-correctable bits during an error correction operation of data read from the target memory cells.

### CROSS-REFERENCE TO RELATED APPLICATION

The present application claims priority under 35 U.S.C. § 119(a) to Korean patent application number 10-2024-0174960 filed on Nov. 29, 2024, in the Korean Intellectual Property Office, the entire disclosure of which is incorporated herein by reference.

### BACKGROUND

### 1. Technical Field

Various embodiments of the present disclosure generally relate to a semiconductor device, and more particularly, to a storage device for determining a read voltage and a method of operating the storage device.

### 2. Related Art

A storage device may store data under the control of a host device, which may include a computer, a mobile device such as a smartphone, a tablet PC, or other various electronic devices. The storage device may include a memory device storing data and a memory controller controlling the memory device.

The storage device may perform a read operation to read data stored in a plurality of memory cells included in the memory device. As the number of read operations increases, threshold voltages of the memory cells may change. Therefore, threshold voltage distributions of the memory cells programmed to different states may overlap, leading to an increase in the number of memory cells that are difficult to distinguish through a read voltage. As the number of indistinguishable memory cells increases, the probability of a read operation failing also rises.

### SUMMARY

Various embodiments are directed to a storage device for determining an optimal read voltage based on a threshold voltage distribution of memory cells and the number of error-correctable bits.

According to an embodiment of the present disclosure, a storage device may include: a memory device including a plurality of memory cells corresponding to a plurality of threshold voltage distributions; and a memory controller configured to determine an optimal read voltage for a read operation of target memory cells associated with a first threshold voltage distribution among the plurality of threshold voltage distributions, based on an average threshold voltage of the first threshold voltage distribution, a standard deviation of the first threshold voltage distribution, and a number of error-correctable bits during error correction of data read from the target memory cells.

According to an embodiment of the present disclosure, a method of operating a storage device may include: determining a number of first memory cells distinguished by a first read voltage among target memory cells corresponding to a first threshold voltage distribution; determining a number of second memory cells distinguished by a second read voltage among memory cells corresponding to a second threshold voltage distribution adjacent to the first threshold voltage distribution; calculating an average threshold voltage of the first threshold voltage distribution based on the first read voltage, the number of first memory cells, and a predetermined number of memory cells corresponding to the first threshold voltage distribution; calculating an average threshold voltage of the second threshold voltage distribution based on the second read voltage, the number of second memory cells, and a predetermined number of memory cells corresponding to the second threshold voltage distribution; estimating a standard deviation of the first threshold voltage distribution based on the average threshold voltage of the first threshold voltage distribution and the average threshold voltage of the second threshold voltage distribution; and determining an optimal read voltage for reading the target memory cells based on the average threshold voltage of the first threshold voltage distribution, the standard deviation of the first threshold voltage distribution, the predetermined number of memory cells corresponding to the first threshold voltage distribution, and a number of error-correctable bits during error correction of data read from the target memory cells corresponding to the first threshold voltage distribution.

According to an embodiment of the present disclosure, a storage device may include: a memory device including a plurality of memory cells each corresponding to one of a plurality of states defined based on a threshold voltage; and a memory controller configured to determine an optimal read voltage a read operation of a target memory cell among the plurality of memory cells, based on statistical data of a threshold voltage distribution corresponding to the target memory cell and a number of error-correctable bits during error correction of data read from the target memory cell.

### BRIEF DESCRIPTION OF THE DRAWINGS

FIG. 1 is a diagram illustrating a storage device according to an embodiment of the present disclosure.

FIG. 2 is a diagram illustrating threshold voltage distributions of a plurality of memory cells according to an embodiment of the present disclosure.

FIG. 3 is a diagram illustrating an example of calculating the number of memory cells that can be distinguished by a predetermined read voltage according to an embodiment of the present disclosure.

FIG. 4 is a diagram illustrating an example of calculating an average threshold voltage of a threshold voltage distribution according to an embodiment of the present disclosure.

FIG. 5 is a diagram illustrating an example of estimating a standard deviation of a threshold voltage distribution according to an embodiment of the present disclosure.

FIG. 6 is a diagram illustrating an example of determining an optimal read voltage according to an embodiment of the present disclosure.

FIG. 7 is a flowchart illustrating a method of operating a storage device according to an embodiment of the present disclosure.

FIG. 8 is a diagram illustrating a memory controller according to an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure may be implemented in various forms, and should not be construed as limited to the embodiments set forth herein.

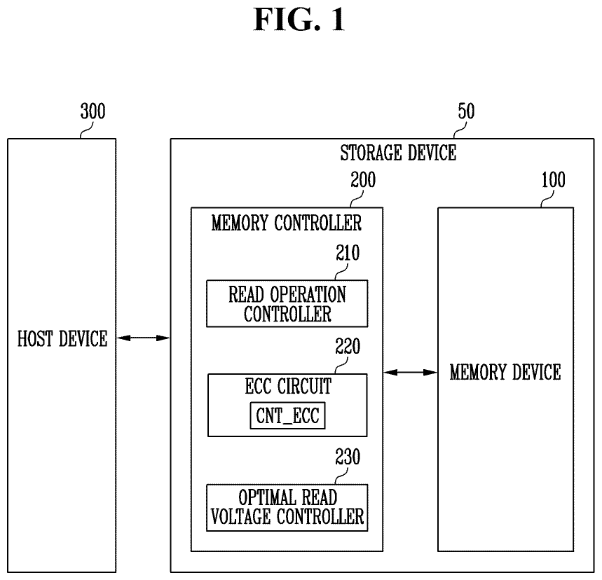

FIG. 1 is a diagram illustrating a storage device 50 according to an embodiment of the present disclosure.

Referring to FIG. 1, the storage device 50 may include a memory device 100 and a memory controller 200 controlling the memory device 100. The storage device 50 is a device storing data under the control of a host device 300, such as a cell phone, smartphone, MP3 player, laptop computer, desktop computer, gaming machine, television, tablet PC, or in-vehicle infotainment system.

The storage device 50 may be configured as one of various types of storage devices such as a solid-state drive (SSD), a multimedia card in the form of a multimedia card (MMC), (e.g., an eMMC, an RS-MMC, or a micro-MMC), a secure digital (SD) card in the form of an SD (e.g., a mini-SD or a micro-SD), a universal serial bus (USB) storage device, a universal flash storage (UFS) device, a personal computer memory card international association (PCMCIA) card type storage device, a peripheral component interconnect (PCI) card type storage device, a PCI express (PCI-e) card type storage device, a compact flash (CF) card, a smart media card, or a memory stick.

The storage device 50 may be manufactured as one of various types of packages. For example, the storage device 50 may be manufactured as one of various kinds of package types, such as a package on package (POP), a system in package (SIP), a system on chip (SOC), a multi-chip package (MCP), a chip on board (COB), a wafer-level fabricated package (WFP), and a wafer-level stack package (WSP).

The memory device 100 may store data. The memory device 100 may operate under the control of the memory controller 200. The memory device 100 may include a plurality of memory blocks storing data. Each memory block may include a plurality of memory cells. Each of the plurality of memory cells may be configured as a multi-level cell (MLC) storing two bits of data, a triple-level cell (TLC) storing three bits of data, a quad-level cell (QLC) storing four bits of data, or the like.

In an embodiment, the memory device 100 may be a non-volatile memory which retains stored data even when supply of power is interrupted or blocked. By way of example, the memory device 100 is a NAND flash memory device in the context of the following description.

In an embodiment, the memory device 100 may receive a command and an address from the memory controller 200. The memory device 100 may perform an operation directed by the command on a region selected by the address. For example, the memory device 100 may perform a write operation (or program operation), a read operation, and an erase operation.

The memory controller 200 may control the overall operation of the storage device 50.

When power is applied to the storage device 50, the memory controller 200 may execute firmware (FW). When the memory device 100 is a flash memory device, the firmware (FW) may include a Host Interface Layer (HIL) that controls communication with the host device 300, a Flash Translation Layer (FTL) that controls communication between the host device 300 and the memory device 100, and a Flash Interface Layer (FIL) that controls communication with the memory device 100.

In an embodiment, the memory controller 200 may receive data and a logical block address (LBA) from the host device 300 and translate the logical block address (LBA) into a physical block address (PBA) that represents an address of memory cells in which data included in the memory device 100 is to be stored. In this specification, the terms “logical block address” and “logic address” or “logical address” may be used interchangeably. In this specification, the terms “physical block address” and “physics address” or “physical address” may be used interchangeably.

In an embodiment, the memory controller 200 may provide a command, an address, or data corresponding to an operation to the memory device 100 to perform a program operation, a read operation, an erase operation, or the like, in response to a request from the host device 300.

In an embodiment, the memory controller 200 may generate and transmit a command, an address, and data to the memory device 100 independently of a request from the host device 300. For example, the memory controller 200 may provide a command, an address, and data to the memory device 100 used for performing program operations and read operations accompanied to perform an internal operation, such as a wear leveling operation, a read reclaim operation, a garbage collection operation, or the like.

In an embodiment, the memory controller 200 may include a read operation controller 210, an error correction code (ECC) circuit 220, and an optimal read voltage controller 230.

The read operation controller 210 may control a read operation of the memory device 100. For example, the read operation controller 210 may provide the memory device 100 with a read command directing to perform a read operation and an address indicating a position in which data to be read is stored.

The ECC circuit 220 may perform an error correction when data is stored in the memory device 100 or when data is read from the memory device 100. For example, the ECC circuit 220 may perform error correction code (ECC) encoding based on data to be written to the memory device 100. The encoded data may be transferred to the memory device 100. The ECC circuit 220 may perform ECC decoding on data received from the memory device 100.

The optimal read voltage controller 230 may control operating voltages used during a read operation.

In an embodiment, the optimal read voltage controller 230 may determine an optimal read voltage to read data stored in the memory cells.

For example, the optimal read voltage controller 230 may determine an optimal read voltage for a read operation of target memory cells, among the plurality of memory cells, based on statistical data of a threshold voltage distribution corresponding to the target memory cells and the number of error-correctable bits during an error correction operation of data read from the target memory cells.

In an embodiment, the statistical data of the threshold voltage distribution may include at least one of an average threshold voltage or a standard deviation of the threshold voltage distribution.

In an embodiment, the optimal read voltage controller 230 may calculate the number of memory cells having a threshold voltage less than a predetermined read voltage, among memory cells corresponding to the threshold voltage distribution. In another embodiment, the optimal read voltage controller 230 may calculate the number of memory cells having a threshold voltage greater than the predetermined read voltage, among the memory cells corresponding to the threshold voltage distribution. Hereinafter, an example of calculating the average threshold voltage based on the number of memory cells having the threshold voltage less than the predetermined read voltage will be described.

Further, the optimal read voltage controller 230 may calculate the average threshold voltage of the threshold voltage distribution based on the predetermined read voltage, the number of memory cells having a threshold voltage less than the predetermined read voltage, and a predetermined number of memory cells corresponding to the threshold voltage distribution.

Further, the plurality of memory cells may correspond to a plurality of threshold voltage distributions. The optimal read voltage controller 230 may calculate a standard deviation of a first threshold voltage distribution based on an average threshold voltage of the first threshold voltage distribution corresponding to a target memory cell and an average threshold voltage of a second threshold voltage distribution adjacent to the first threshold voltage distribution. In an embodiment, the average threshold voltage of the first threshold voltage distribution may be less than the average threshold voltage of the second threshold voltage distribution.

In addition, the optimal read voltage controller 230 may estimate the standard deviation of the first threshold voltage distribution based on the average threshold voltage of the first threshold voltage distribution corresponding to the target memory cell and the average threshold voltage of the second threshold voltage distribution adjacent to the first threshold voltage distribution.

Further, the optimal read voltage controller 230 may determine an optimal read voltage used for the read operation of the target memory cells based on the average threshold voltage of the first threshold voltage distribution, the standard deviation of the first threshold voltage distribution, a predetermined number of memory cells corresponding to the first threshold voltage distribution, and the number of error-correctable bits.

In an embodiment, the number of error-correctable bits CNT_ECC may refer to the maximum number of bits that can be corrected during an error correction operation performed by the ECC circuit 220. For example, the ECC circuit 220 may correct errors within the number of error-correctable bits CNT_ECC during an error correction operation on read data. If the data read from the target memory cells includes error bits that exceed the number of error-correctable bits CNT_ECC, the memory controller 200 may determine that the read operation for the target memory cells has failed.

In an embodiment, the number of error-correctable bits CNT_ECC respectively corresponding to the plurality of threshold voltage distributions may be either different or the same.

In an embodiment, the optimal read voltage may be a read voltage used to distinguish memory cells corresponding to a third threshold voltage distribution, which is adjacent to the first threshold voltage distribution, from among the target memory cells and the plurality of memory cells. The average threshold voltage of the first threshold voltage distribution may be greater than an average threshold voltage of the third threshold voltage distribution. The third threshold voltage distribution may be adjacent to the first threshold voltage distribution on the opposite side of the second threshold voltage distribution.

In an embodiment, the read operation controller 210 may perform a read operation on the target memory cells using the determined optimal read voltage.

The host device 300 may communicate with the storage device 50 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnect (PCI), PCI Express (PCI-e), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and Load Reduced DIMM (LRDIMM) communication methods.

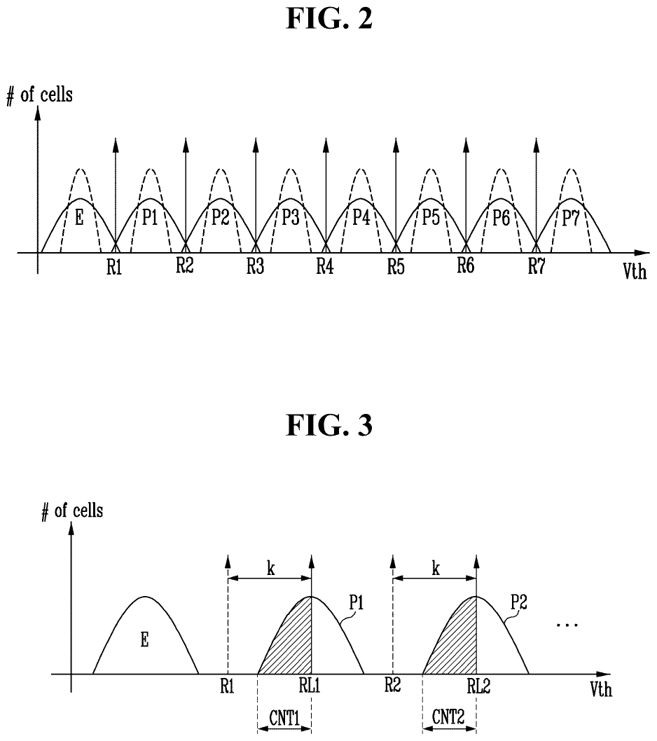

FIG. 2 is a diagram illustrating the threshold voltage distributions of the plurality of memory cells according to an embodiment of the present disclosure. In an embodiment of the present disclosure, a threshold voltage distribution of memory cells programmed using a triple-level cell method is described as an example. However, embodiments described below may also be applied to a threshold voltage distribution of memory cells programmed using a multi-level cell method, a quad-level cell method, or the like.

In FIG. 2, the horizontal axis of the graph represents a magnitude of a threshold voltage (Vth) and the vertical axis of the graph represents the number of memory cells (# of cells).

Referring to FIG. 2, each of the memory cells may correspond to one of a plurality of states distinguished based on its threshold voltage. For example, the plurality of states may include an erase state E and first to seventh program states P1 to P7.

Among the memory cells, memory cells having the erase state E as their program state may have a threshold voltage corresponding to the erase state E.

In addition, among the memory cells, memory cells having the first program state P1 as their program state may have a threshold voltage corresponding to the first program state P1.

Further, among the memory cells, memory cells having the second program state P2 as their program state may have a threshold voltage corresponding to the second program state P2.

Further, among the memory cells, memory cells having the third program state P3 as their program state may have a threshold voltage corresponding to the third program state P3.

Further, among the memory cells, memory cells having the fourth program state P4 as their program state may have a threshold voltage corresponding to the fourth program state P4.

Further, among the memory cells, memory cells having the fifth program state P5 as their program state may have a threshold voltage corresponding to the fifth program state P5.

Further, among the memory cells, memory cells having the sixth program state P6 as their program state may have a threshold voltage corresponding to the sixth program state P6.

Further, among the memory cells, memory cells having the seventh program state P7 as their program state may have a threshold voltage corresponding to the seventh program state P7.

In an embodiment, the plurality of states may correspond to a plurality of threshold voltage distributions. For example, a plurality of memory cells in the plurality of states may align with the plurality of threshold voltage distributions. Each of the plurality of threshold voltage distributions may follow the form of a Gaussian distribution.

In an embodiment, a predetermined number of memory cells corresponding to each threshold voltage distribution may be the same. For example, the memory controller 200 may include a scrambler that alters a pattern of data to be programmed to the memory device 100, ensuring that a first state (e.g., “1”) and a second state (e.g., “0”) of the data remain probabilistically constant. The scrambled data may be then stored in a plurality of memory cells, which are evenly distributed across different threshold voltage distributions. For example, assuming the total number of memory cells corresponding to the entire threshold voltage distribution is K, each threshold voltage distribution may correspond to K/8 memory cells.

Alternatively, the predetermined number of memory cells corresponding to each threshold voltage distribution may vary.

In an embodiment, during a read operation, the plurality of states E and P1 to P7 may be distinguished by a reference read voltage. The reference read voltage may be a predetermined read voltage. For example, a first reference read voltage R1 may be used to distinguish between memory cells in the erase state E and memory cells in the first program state P1. A second reference read voltage R2 may be used to distinguish between memory cells in the first program state P1 and memory cells in the second program state P2. A third reference read voltage R3 may be used to distinguish between memory cells in the second program state P2 and memory cells in the third program state P3. A fourth reference read voltage R4 may be used to distinguish between memory cells in the third program state P3 and memory cells in the fourth program state P4. A fifth reference read voltage R5 may be used to distinguish between memory cells in the fourth program state P4 and memory cells in the fifth program state P5. A sixth reference read voltage R6 may be used to distinguish between memory cells in the fifth program state P5 and memory cells in the sixth program state P6. A seventh reference read voltage R7 may be used to distinguish between memory cells in the sixth program state P6 and memory cells in the seventh program state P7.

As the number of read operations increases, the threshold voltages of the memory cells may shift. For example, immediately after data is programmed, threshold voltage distributions corresponding to different states may remain distinct, as represented by dashed lines in FIG. 2. However, with repeated read operations, the threshold voltage distributions may begin to overlap, as represented by solid lines in FIG. 2. This overlap increases the number of memory cells that cannot be reliably distinguished using a read voltage, thereby reducing the success rate of the read operations.

To address this issue, the following describes a method of determining an optimal read voltage to increase the success rate of read operations by analyzing statistical data of the threshold voltage distributions and considering the number of error-correctable bits.

Furthermore, as an example, embodiments for determining an optimal read voltage used to distinguish between memory cells in the erase state E and target memory cells in the first program state P1 will be described below with reference to FIGS. 3 to 8. The principles outlined in the embodiments may also be applied to determine an optimal read voltage for distinguishing memory cells in states other than the erase state E and the first program state P1.

FIG. 3 is a diagram illustrating an example of calculating the number of memory cells distinguished by a predetermined read voltage according to an embodiment of the present disclosure. Specifically, FIG. 3 illustrates shapes of respective threshold voltage distributions formed immediately after performing a program operation.

Referring to FIG. 3, the memory controller 200 may calculate the number of memory cells distinguished by a predetermined read voltage within each of the threshold voltage distributions.

In an embodiment, the memory controller 200 may calculate the number of memory cells CNT1 that are distinguished by a predetermined first read voltage RL1 within the first threshold voltage distribution corresponding to the first program state P1. For example, the predetermined first read voltage RL1 may have a voltage level that is greater than that of the first reference read voltage R1 by a k value.

In an embodiment, the memory controller 200 may calculate the number of first memory cells CNT1 having a threshold voltage less than the predetermined first read voltage RL1, among target memory cells corresponding to the first threshold voltage distribution. For example, the first memory cells may refer to memory cells included in a hatched region of the first threshold voltage distribution.

For example, the memory controller 200 may determine the number of memory cells having a first bit value based on a read operation performed using the predetermined first read voltage RL1, among the target memory cells, as the number of first memory cells CNT1. The first bit value may be a bit value of memory cells having a threshold voltage less than a read voltage used during the read operation. The first bit value may be either ‘0’ or ‘1.’ For example, among the plurality of memory cells corresponding to the plurality of threshold voltage distributions, the memory cells having the threshold voltage less than the predetermined first read voltage RL1 may include one or more of the memory cells in the erase state E and the first memory cells in the first program state P1. Therefore, the number of first memory cells CNT1 may be calculated by subtracting the number of memory cells in the erase state E CNT_E from the number of first bit values included in data read using the predetermined first read voltage RL1.

In an embodiment, the memory controller 200 may calculate the number of memory cells CNT2 that are distinguished by a predetermined second read voltage RL2 in the second threshold voltage distribution corresponding to the second program state P2. For example, the predetermined second read voltage RL2 may have a voltage level greater than that of the second reference read voltage R2 by the k value.

In an embodiment, the memory controller 200 may calculate the number of second memory cells CNT2 having a threshold voltage less than the predetermined second read voltage RL2, among memory cells corresponding to the second threshold voltage distribution. For example, the second memory cells may refer to memory cells included in a hatched region of the second threshold voltage distribution.

For example, the memory controller 200 may determine the number of memory cells having the first bit value based on a read operation performed using the predetermined second read voltage RL2, among the memory cells corresponding to the second threshold voltage distribution, as the number of second memory cells CNT2. For example, among the plurality of memory cells corresponding to the plurality of threshold voltage distributions, the memory cells having the threshold voltage less than the predetermined second read voltage RL2 may include one or more of the memory cells in the erase state E, the memory cells in the first program state P1, and the second memory cells in the second program state P2. Therefore, the number of second memory cells CNT2 may be calculated by subtracting the number of memory cells in the erase state E CNT_E and the number of memory cells in the first program state P1 CNT_P1 from the number of first bit values included in data read using the predetermined second read voltage RL2.

In an embodiment, the number of memory cells in the erase state E CNT_E, the number of memory cells in the first program state P1 CNT_P1, and the number of memory cells in the second program state P2 CNT_P2 may be the same or different from each other.

In the example described above, memory cells distinguished by a predetermined read voltage have a threshold voltage less than the predetermined read voltage. However, this is not a limitation, as the memory cells distinguished by the predetermined read voltage may also have a threshold voltage greater than the predetermined read voltage.

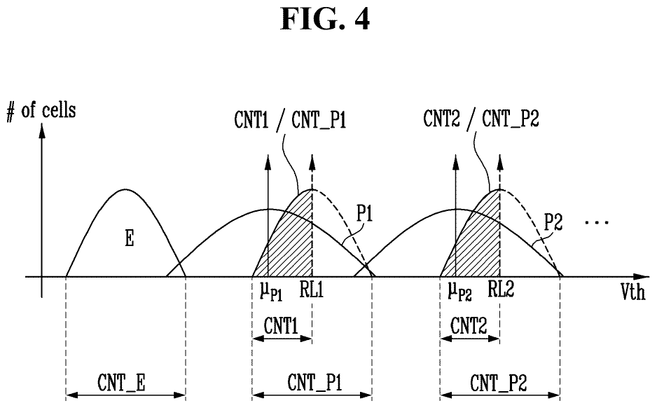

FIG. 4 is a diagram illustrating an example of calculating an average threshold voltage of a threshold voltage distribution according to an embodiment of the present disclosure. In FIG. 4, threshold voltage distributions represented by dashed lines may refer to threshold voltage distributions formed immediately after performing a program operation on memory cells. Threshold voltage distributions represented by solid lines may refer to threshold voltage distributions formed after performing a read operation on the memory cells a predetermined number of times.

Referring to FIG. 4, the memory controller 200 may calculate an average threshold voltage μₚ_{₁} of the first threshold voltage distribution based on the first read voltage RL1 and a first inverse Q-function value corresponding to a ratio of the first memory cells distinguished by the first read voltage RL1 to the target memory cells corresponding to the first threshold voltage distribution.

In an embodiment, the ratio of the first memory cells to the target memory cells may be a ratio of the number of first memory cells CNT1 to the predetermined number of memory cells CNT_P1 corresponding to the first threshold voltage distribution. The number of first memory cells CNT1 may be the number of memory cells determined to have the first bit value as a result of the read operation performed using the first read voltage RL1 among the target memory cells. The predetermined number of memory cells CNT_P1 corresponding to the first threshold voltage distribution may refer to the number of target memory cells.

In an embodiment, the average threshold voltage μₚ_{₁} of the first threshold voltage distribution may be calculated using Equation 1 below.

$$\text{?} = RL 1 - {σ}_{1} \times {Q}^{- 1} ( CNT 1 / CNT\_P1 ) \qquad [ Equation 1 ]$$

$$\text{?} \text{indicates text missing or illegible when filed}$$

In Equation 1, σ₁ is a constant, which is a predetermined value, and Q⁻¹ may refer to an inverse Q-function.

For example, the average threshold voltage μₚ_{₁} of the first threshold voltage distribution may be calculated as the first read voltage RL1 minus the product of the predetermined value σ₁ and the first inverse Q-function value. The first inverse Q-function value may be an inverse Q-function value for the ratio of the number of first memory cells CNT1 to the predetermined number of memory cells CNT_P1 corresponding to the first threshold voltage distribution.

In an embodiment, the memory controller 200 may calculate an average threshold voltage μₚ_{₂} of the second threshold voltage distribution based on the second read voltage RL2 and a second inverse Q-function value corresponding to a ratio of the second memory cells distinguished by the second read voltage RL2 to the memory cells corresponding to the second threshold voltage distribution.

In an embodiment, the ratio of the second memory cells to the memory cells corresponding to the second threshold voltage distribution may be a ratio of the number of second memory cells CNT2 to the predetermined number of memory cells CNT_P2 corresponding to the second threshold voltage distribution. The number of second memory cells CNT2 may be the number of memory cells CNT2 determined to have the first bit value as a result of the read operation performed using the second read voltage RL2 among the memory cells corresponding to the second threshold voltage distribution.

In an embodiment, the average threshold voltage μₚ_{₂} of the second threshold voltage distribution may be calculated using Equation 2 below.

$$\text{?} = RL 2 - {σ}_{2} \times {Q}^{- 1} ( CNT 2 / CNT\_P2 ) \qquad [ Equation 2 ]$$

$$\text{?} \text{indicates text missing or illegible when filed}$$

In Equation 2, σ₂ is a constant, which may be a predetermined value. The predetermined value σ₂ in Equation 2 may be the same as or different from the predetermined value σ₁ in Equation 1.

For example, the average threshold voltage μₚ_{₂} of the second threshold voltage distribution may be calculated as the second read voltage RL2 minus the product of the predetermined value σ₂ and the second inverse Q-function value. The second inverse Q-function value may be an inverse Q-function value for the ratio of the number of second memory cells CNT2 to the predetermined number of memory cells CNT_P2 corresponding to the second threshold voltage distribution.

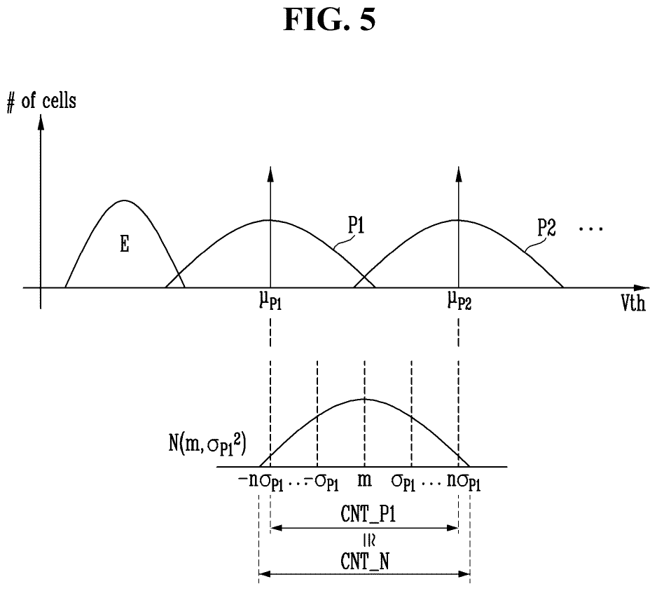

FIG. 5 is a diagram illustrating an example of estimating a standard deviation of a threshold voltage distribution according to an embodiment of the present disclosure. In FIG. 5, as an example, the predetermined number of memory cells corresponding to the first threshold voltage distribution is equal to the predetermined number of memory cells corresponding to the second threshold voltage distribution. However, the following descriptions may also be applied to an example in which the predetermined number of memory cells corresponding to the first threshold voltage distribution is different from the predetermined number of memory cells corresponding to the second threshold voltage distribution. The predetermined number of memory cells corresponding to the first threshold voltage distribution may be the number of target memory cells.

Referring to FIG. 5, the memory controller 200 may estimate a standard deviation μₚ_{₁} of the first threshold voltage distribution based on the average threshold voltage μₚ_{₁} of the first threshold voltage distribution and the average threshold voltage μₚ_{₂} of the second threshold voltage distribution.

Because the average threshold voltage μₚ_{₁} of the first threshold voltage distribution corresponds to the median value of the first threshold voltage distribution, the memory cells having the threshold voltage greater than the average threshold voltage μₚ_{₁} of the first threshold voltage distribution among the target memory cells corresponding to the first threshold voltage distribution may correspond to half of the target memory cells.

Further, because the average threshold voltage μₚ_{₂} of the second threshold voltage distribution corresponds to the median value of the second threshold voltage distribution, the memory cells having the threshold voltage less than the average threshold voltage μₚ_{₂} of the second threshold voltage distribution among the memory cells corresponding to the second threshold voltage distribution may correspond to half of the memory cells corresponding to the second threshold voltage distribution.

Thus, the number of memory cells CNT_P1 between the average threshold voltage μₚ_{₁} of the first threshold voltage distribution and the average threshold voltage wiz of the second threshold voltage distribution may correspond to a sum of half of the number of target memory cells and half of the number of memory cells corresponding to the second threshold voltage distribution. Because the number of target memory cells is equal to the number of memory cells corresponding to the second threshold voltage distribution, the number of memory cells CNT_P1 between the average threshold voltage μₚ_{₁} of the first threshold voltage distribution and the average threshold voltage μₚ_{₂} of the second threshold voltage distribution may be the same as the number of target memory cells.

In an embodiment, a threshold voltage distribution formed based on the average threshold voltage μₚ_{₁} of the first threshold voltage distribution and the average threshold voltage μₚ_{₂} of the second threshold voltage distribution may be assumed to be represented by N(m·σₚ_{₁}²). For example, the formed threshold voltage distribution may have a median value m between the average threshold voltage μₚ_{₁} of the first threshold voltage distribution and the average threshold voltage μₚ_{₂} of the second threshold voltage distribution as a mean, with the standard deviation σₚ_{₁} of the first threshold voltage distribution as the standard deviation. If it is estimated that the average threshold voltage μₚ_{₁} of the first threshold voltage distribution and the average threshold voltage μₚ_{₂} of the second threshold voltage distribution correspond to n standard deviations −nσₚ_{₁} and nσₚ_{₁}, respectively, on opposite sides of the median value m, the number of memory cells corresponding to the formed threshold voltage distribution CNT_N may approximate the number of memory cells CNT_P1 between the average threshold voltage μₚ_{₁} of the first threshold voltage distribution and the average threshold voltage μₚ_{₂} of the second threshold voltage distribution, where n may be a real number greater than zero.

In an embodiment, the standard deviation σₚ_{₁} of the first threshold voltage distribution may be approximated using Equation 3 below.

$$\text{?} = \frac{\text{?} + \text{?}}{2 n} \qquad [ Equation 3 ]$$

$$\text{?} \text{indicates text missing or illegible when filed}$$

For example, the memory controller 200 may calculate a sum of the average threshold voltage μₚ_{₁} of the first threshold voltage distribution and the average threshold voltage μₚ_{₂} of the second threshold voltage distribution, and may estimate a ratio of the calculated sum to a predetermined value n as the standard deviation σₚ_{₁} of the first threshold voltage distribution. For example, when the predetermined value n is ‘2,’ approximately 95% of the memory cells corresponding to the formed threshold voltage distribution may fall between the average threshold voltage un of the first threshold voltage distribution and the average threshold voltage μₚ_{₂} of the second threshold voltage distribution. Similarly, when the predetermined value n is ‘3,’ approximately 99% of the memory cells corresponding to the formed threshold voltage distribution may fall between the average threshold voltage μₚ_{₁} of the first threshold voltage distribution and the average threshold voltage μₚ_{₂} of the second threshold voltage distribution.

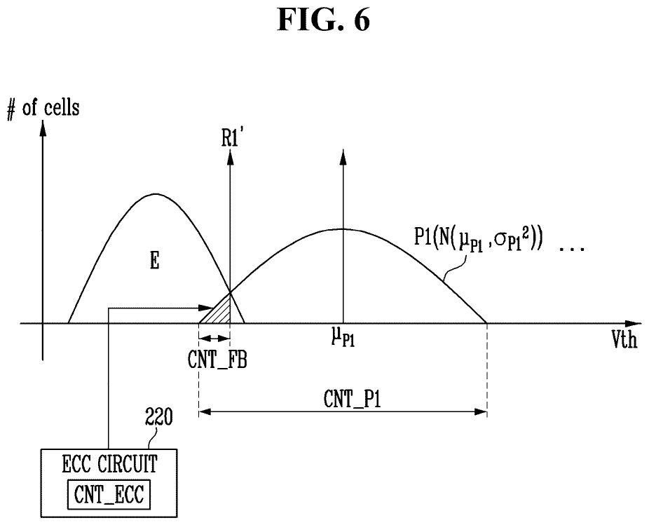

FIG. 6 is a diagram illustrating an example of determining an optimal read voltage according to an embodiment of the present disclosure.

Referring to FIG. 6, the memory controller 200 may determine an optimal read voltage R1′ used for the read operation of the target memory cells based on the average threshold voltage μₚ_{₁} of the first threshold voltage distribution, the standard deviation σₚ_{₁} of the first threshold voltage distribution, and the number of error-correctable bits CNT_ECC during an error correction operation on the data read from the target memory cells corresponding to the first threshold voltage distribution.

In an embodiment, the number of error-correctable bits CNT_ECC may refer to the maximum number of error-correctable bits in the data read from the target memory cells. If the data read from the target memory cells includes error bits that exceed the number of error-correctable bits CNT_ECC, the read operation on the target memory cells may fail. For example, in FIG. 6, a hatched region of the first threshold voltage distribution that overlaps with the threshold voltage distribution corresponding to the erase state E may indicate an error region. If the number of error bits CNT_FB included in the error region exceeds the number of error-correctable bits CNT_ECC, the read operation on the target memory cells may fail. Conversely, if the number of error bits CNT_FB included in the error region does not exceed the number of error-correctable bits CNT_ECC, the read operation on the target memory cells may succeed.

In an embodiment, the optimal read voltage R1′ may be determined using Equation 4 below.

$$R {1}^{′} = \text{?} + \text{?} \times {Q}^{- 1} ( CNT\_ECC / CNT\_P1 ) \qquad [ Equation 4 ]$$

$$\text{?} \text{indicates text missing or illegible when filed}$$

For example, the memory controller 200 may calculate a third inverse Q-function value corresponding to a ratio of the number of error-correctable bits CNT_ECC to the predetermined number of memory cells CNT_P1 corresponding to the first threshold voltage distribution. The memory controller 200 may calculate a product of the standard deviation σₚ_{₁} of the first threshold voltage distribution and the calculated third inverse Q-function value, and may determine the optimal read voltage R1′ as a sum of the calculated product and the average threshold voltage μₚ_{₁} of the first threshold voltage distribution.

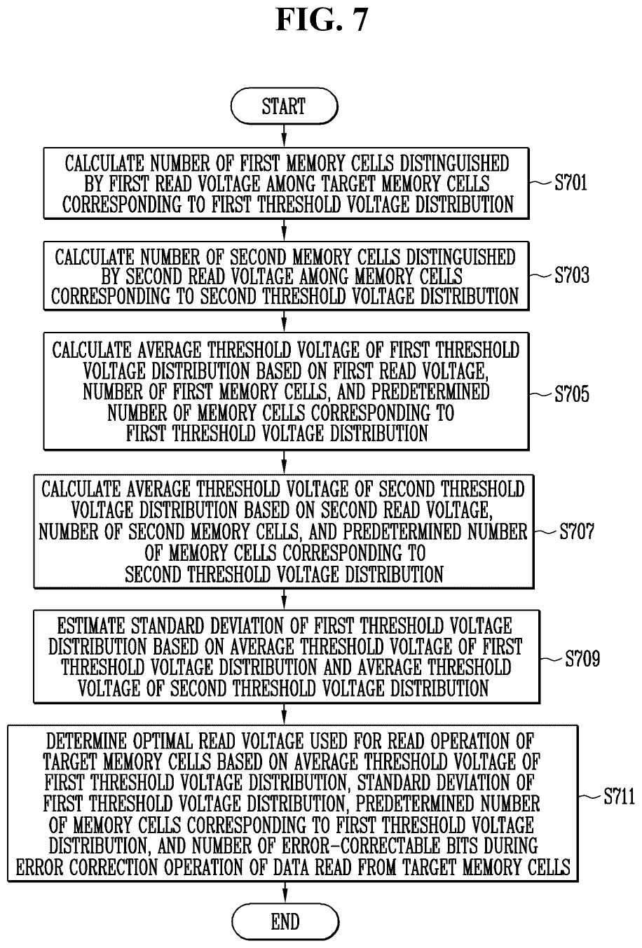

FIG. 7 is a flowchart illustrating a method of operating a storage device according to an embodiment of the present disclosure. The method illustrated in FIG. 7 may be performed, for example, by the storage device 50 shown in FIG. 1.

Referring to FIG. 7, at step S701, the storage device 50 may calculate the number of first memory cells, distinguished by a first read voltage, among target memory cells corresponding to a first threshold voltage distribution.

At step S703, the storage device 50 may calculate the number of second memory cells, distinguished by a second read voltage, among memory cells corresponding to a second threshold voltage distribution that is adjacent to the first threshold voltage distribution.

At step S705, the storage device 50 may calculate an average threshold voltage of the first threshold voltage distribution based on the first read voltage, the number of first memory cells, and a predetermined number of memory cells corresponding to the first threshold voltage distribution.

For example, the storage device 50 may calculate a first inverse Q-function value corresponding to a ratio of the number of first memory cells to the predetermined number of memory cells corresponding to the first threshold voltage distribution.

Further, the storage device 50 may calculate the average threshold voltage of the first threshold voltage distribution based on the first read voltage and the calculated first inverse Q-function value.

At step S707, the storage device 50 may calculate an average threshold voltage of the second threshold voltage distribution based on the second read voltage, the number of second memory cells, and a predetermined number of memory cells corresponding to the second threshold voltage distribution.

For example, the storage device 50 may calculate a second inverse Q-function value corresponding to a ratio of the number of second memory cells to the predetermined number of memory cells corresponding to the second threshold voltage distribution.

Further, the storage device 50 may calculate the average threshold voltage of the second threshold voltage distribution based on the second read voltage and the calculated second inverse Q-function value.

At step S709, the storage device 50 may estimate a standard deviation of the first threshold voltage distribution based on the average threshold voltage of the first threshold voltage distribution and the average threshold voltage of the second threshold voltage distribution.

For example, the storage device 50 may calculate a sum of the average threshold voltage of the first threshold voltage distribution and the average threshold voltage of the second threshold voltage distribution.

Further, the storage device 50 may estimate a ratio of the calculated sum to a predetermined value as the standard deviation of the first threshold voltage distribution.

At step S711, the storage device 50 may determine an optimal read voltage used for a read operation of the target memory cells based on the average threshold voltage of the first threshold voltage distribution, the standard deviation of the first threshold voltage distribution, the predetermined number of memory cells corresponding to the first threshold voltage distribution, and the number of error-correctable bits during an error correction operation on data read from the target memory cells.

For example, the storage device 50 may calculate a third inverse Q-function value corresponding to a ratio of the number of error-correctable bits to the predetermined number of memory cells corresponding to the first threshold voltage distribution.

Further, the storage device 50 may calculate a product of the standard deviation of the first threshold voltage distribution and the calculated third inverse Q-function value.

Further, the storage device 50 may determine the optimal read voltage as a sum of the calculated product and the average threshold voltage of the first threshold voltage distribution.

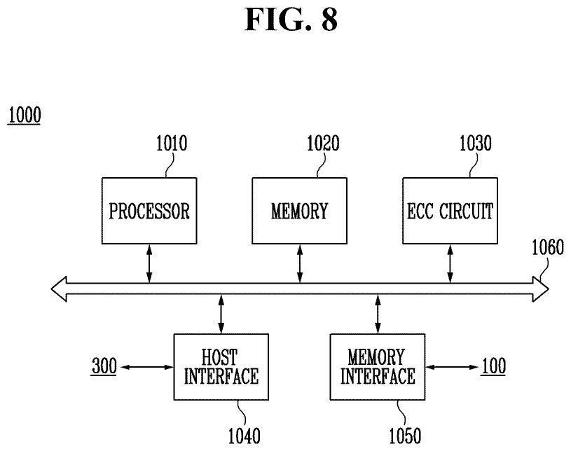

FIG. 8 is a diagram illustrating a memory controller 1000 according to an embodiment of the present disclosure.

The memory controller 1000 shown in FIG. 8 may correspond to the memory controller 200 shown in FIG. 1.

Referring to FIG. 8, the memory controller 1000 may include a processor 1010, memory 1020, an error correction code (ECC) circuit 1030, a host interface 1040, a memory interface 1050, and a communication bus 1060. In the memory controller 1000, the processor 1010, the memory 1020, the ECC circuit 1030, the host interface 1040, and the memory interface 1050 may communicate with each other via the communication bus 1060.

Also, the ECC circuit 1030 shown in FIG. 8 may correspond to the ECC circuit 220 shown in FIG. 1. Accordingly, a detailed description for the ECC circuit 1030 will be omitted.

The processor 1010 may execute firmware, a code, or one or more commands that include various information necessary for the operation of the memory controller 1000. In an embodiment, the read operation controller 210 and the optimal read voltage controller 230 of FIG. 1 may be components included in the processor 1010.

In an embodiment, the processor 1010 may determine an optimal read voltage for performing a read operation on target memory cells among a plurality of memory cells. This determination may be based on statistical data of a threshold voltage distribution corresponding to the target memory cells and the number of error-correctable bits during an error correction operation on data read from the target memory cells. The statistical data of the threshold voltage distribution may include parameters such as an average threshold voltage, a variance, a standard deviation, or the like of the threshold voltage distribution.

The memory 1020 may be used as buffer memory, cache memory, operating memory, or the like.

The memory 1020 may store firmware, a code, or one or more commands that include various information necessary for the operation of the memory controller 1000.

The memory controller 1000 may communicate with an external device (for example, the host device 300 of FIG. 1, an application processor, or the like) via the host interface 1040.

The memory controller 1000 may communicate with the memory device 100 via the memory interface 1050. The memory controller 1000 may transmit a command, an address, a control signal, or the like to the memory device 100, and may receive data from the memory device 100 via the memory interface 1050.

According to embodiments of the present disclosure, a storage device capable of improving the success rate of a read operation and a method of operating the storage device are provided.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A storage device, comprising:
a memory device including a plurality of memory cells corresponding to a plurality of threshold voltage distributions; and
a memory controller configured to determine an optimal read voltage for a read operation of target memory cells associated with a first threshold voltage distribution among the plurality of threshold voltage distributions, based on an average threshold voltage of the first threshold voltage distribution, a standard deviation of the first threshold voltage distribution, and a number of error-correctable bits during error correction of data read from the target memory cells.

2. The storage device of claim 1, wherein the memory controller calculates the average threshold voltage of the first threshold voltage distribution based on a first read voltage and a first inverse Q-function value corresponding to a ratio of first memory cells, distinguished by the first read voltage, to the target memory cells.

3. The storage device of claim 2, wherein the ratio of the first memory cells is a ratio of a number of memory cells having a first bit value, based on a read operation using the first read voltage, to a predetermined number of memory cells corresponding to the first threshold voltage distribution.

4. The storage device of claim 1, wherein the memory controller estimates the standard deviation of the first threshold voltage distribution based on the average threshold voltage of the first threshold voltage distribution and an average threshold voltage of a second threshold voltage distribution adjacent to the first threshold voltage distribution among the plurality of threshold voltage distributions.

5. The storage device of claim 4, wherein the average threshold voltage of the first threshold voltage distribution is less than the average threshold voltage of the second threshold voltage distribution.

6. The storage device of claim 4, wherein the memory controller calculates the average threshold voltage of the second threshold voltage distribution based on a second read voltage and a second inverse Q-function value corresponding to a ratio of second memory cells, distinguished by the second read voltage, to memory cells corresponding to the second threshold voltage distribution.

7. The storage device of claim 6, wherein the ratio of the second memory cells is a ratio of a number of memory cells having a first bit value, based on a read operation using the second read voltage, to a predetermined number of memory cells corresponding to the second threshold voltage distribution.

8. The storage device of claim 4, wherein the memory controller is configured to:
calculate a sum of the average threshold voltage of the first threshold voltage distribution and the average threshold voltage of the second threshold voltage distribution; and
estimate the standard deviation of the first threshold voltage distribution as a ratio of the calculated sum to a predetermined value.

9. The storage device of claim 1, wherein the memory controller is configured to:
calculate a third inverse Q-function value corresponding to a ratio of the number of error-correctable bits to a predetermined number of memory cells corresponding to the first threshold voltage distribution;
calculate a product of the standard deviation of the first threshold voltage distribution and the calculated third inverse Q-function value; and
determine the optimal read voltage as a sum of the calculated product and the average threshold voltage of the first threshold voltage distribution.

10. The storage device of claim 1, wherein the memory controller is configured to determine that the read operation on the target memory cells has failed when the data read from the target memory cells includes error bits exceeding the number of error-correctable bits.

11. The storage device of claim 1, wherein the optimal read voltage is used to distinguish the target memory cells from memory cells corresponding to a third threshold voltage distribution adjacent to the first threshold voltage distribution among the plurality of memory cells.

12. The storage device of claim 11, wherein the average threshold voltage of the first threshold voltage distribution is greater than an average threshold voltage of the third threshold voltage distribution.

13. A method of operating a storage device, the method comprising:
determining a number of first memory cells distinguished by a first read voltage among target memory cells corresponding to a first threshold voltage distribution;
determining a number of second memory cells distinguished by a second read voltage among memory cells corresponding to a second threshold voltage distribution adjacent to the first threshold voltage distribution;
calculating an average threshold voltage of the first threshold voltage distribution based on the first read voltage, the number of first memory cells, and a predetermined number of memory cells corresponding to the first threshold voltage distribution;
calculating an average threshold voltage of the second threshold voltage distribution based on the second read voltage, the number of second memory cells, and a predetermined number of memory cells corresponding to the second threshold voltage distribution;
estimating a standard deviation of the first threshold voltage distribution based on the average threshold voltage of the first threshold voltage distribution and the average threshold voltage of the second threshold voltage distribution; and
determining an optimal read voltage for reading the target memory cells based on the average threshold voltage of the first threshold voltage distribution, the standard deviation of the first threshold voltage distribution, the predetermined number of memory cells corresponding to the first threshold voltage distribution, and a number of error-correctable bits during error correction of data read from the target memory cells.

14. The method of claim 13, wherein calculating the average threshold voltage of the first threshold voltage distribution includes:
calculating a first inverse Q-function value corresponding to a ratio of the number of first memory cells to the predetermined number of memory cells corresponding to the first threshold voltage distribution; and
calculating the average threshold voltage of the first threshold voltage distribution based on the first read voltage and the calculated first inverse Q-function value.

15. The method of claim 13, wherein calculating the average threshold voltage of the second threshold voltage distribution includes:
calculating a second inverse Q-function value corresponding to a ratio of the number of second memory cells to the predetermined number of memory cells corresponding to the second threshold voltage distribution; and
calculating the average threshold voltage of the second threshold voltage distribution based on the second read voltage and the calculated second inverse Q-function value.

16. The method of claim 13, wherein estimating the standard deviation includes:
calculating a sum of the average threshold voltage of the first threshold voltage distribution and the average threshold voltage of the second threshold voltage distribution; and
estimating the standard deviation of the first threshold voltage distribution as a ratio of the calculated sum to a predetermined value.

17. The method of claim 13, wherein determining the optimal read voltage includes:
calculating a third inverse Q-function value corresponding to a ratio of the number of error-correctable bits to the predetermined number of memory cells corresponding to the first threshold voltage distribution;
calculating a product of the standard deviation of the first threshold voltage distribution and the calculated third inverse Q-function value; and
determining the optimal read voltage as a sum of the calculated product and the average threshold voltage of the first threshold voltage distribution.

18. A storage device, comprising:
a memory device including a plurality of memory cells, each corresponding to one of a plurality of states defined based on a threshold voltage; and
a memory controller configured to determine an optimal read voltage for a read operation of a target memory cell among the plurality of memory cells, based on statistical data of a threshold voltage distribution corresponding to the target memory cell and a number of error-correctable bits during error correction of data read from the target memory cell.

19. The storage device of claim 18, wherein the statistical data of the threshold voltage distribution includes at least one of an average threshold voltage or a standard deviation of the threshold voltage distribution.
